(19) United States
(12) Patent Application Publication
(10) Pub. No.: US 2016/0219695 A1
(43) Pub. Date: Jul. 28, 2016

(54) METHOD OF FABRICATING DISPLAY DEVICE USING BONDING APPARATUS AND DISPLAY DEVICE

(71) Applicant: SAMSUNG DISPLAY CO., LTD., Yongin-City (KR)

(72) Inventor: Suk Ho CHOI, Cheonan-si (KR)

(21) Appl. No.: 14/740,515

(22) Filed: Jun. 16, 2015

(30) Foreign Application Priority Data
Jan. 27, 2015 (KR) 10-2015-0012557

(51) Int. Cl. H05K 1/02; H05K 1/18; H05K 3/30

(52) U.S. Cl. CPC H05K 1/0281; H05K 3/30; H05K 1/18

(57) ABSTRACT

A method of fabricating a display device using a bonding apparatus, the method including arranging a second substrate on a first substrate in which a plurality of pixels is formed, and bonding the first substrate and the second substrate to each other; providing the first substrate and the second substrate on a stage, and compressing a driver integrated circuit (IC) on the first substrate and simultaneously forming a reinforcing material on the first substrate; and compressing a flexible printed circuit board on the first substrate.

### CROSS-REFERENCE TO RELATED APPLICATION

Korean Patent Application No. 10-2015-0012557, filed on Jan. 27, 2015, in the Korean Intellectual Property Office, and entitled: “Method of Fabricating Display Device Using Bonding Apparatus and Display Device,” is incorporated by reference herein in its entirety.

### BACKGROUND

1. Field

Embodiments relate to a method of fabricating a display device using a bonding apparatus and a display device.

2. Description of the Related Art

Demand for lighter, thinner, shorter, and smaller flat panel display devices has been on the rise with advances in information society. Flat panel display devices may include, for example, a liquid crystal display, an electrophoretic display, an organic light emitting display, an inorganic electroluminescent display, a field emission display, a surface-conduction electron emitter display, a plasma display, and a cathode ray display.

### SUMMARY

Embodiments may be realized by providing a method of fabricating a display device using a bonding apparatus, the method including arranging a second substrate on a first substrate in which a plurality of pixels is formed, and bonding the first substrate and the second substrate to each other; providing the first substrate and the second substrate on a stage, and compressing a driver integrated circuit (IC) on the first substrate and simultaneously forming a reinforcing material on the first substrate; and compressing a flexible printed circuit board on the first substrate.

The bonding apparatus may include a first press and a second press, the driver IC may be compressed on the first substrate using the first press, and the flexible printed circuit board may be compressed on the first substrate using the second press.

Compressing the driver IC and simultaneously forming the reinforcing material may further include aligning the driver IC on the first substrate, and pre-compressing the driver IC under a first temperature and a first pressure for a first time period by the first press and simultaneously discharging the reinforcing material through the first press; and performing a main compression on the driver IC under a second temperature and a second pressure for a second time period by the first press and simultaneously curing the reinforcing material.

The first press may have a plurality of discharge ports formed in a surface of the first press facing the stage to discharge the reinforcing material.

The reinforcing material may be formed on the first substrate between the second substrate and the driver IC.

The reinforcing material may be in liquid form embedded in the first press.

The reinforcing material may be formed of heat-curable resin.

The reinforcing material may have viscosity of 100 cp or higher and 4000 cp or lower.

The first time period may be shorter than the second time period, and the first temperature and the first pressure may be lower than the second temperature and the second pressure.

Compressing the driver IC and simultaneously forming the reinforcing material may further include aligning the driver IC on the first substrate, and pre-compressing the driver IC under a first temperature and a first pressure for a first time period by the first press; performing a main compression on the driver IC under a second temperature and a second pressure for a second time period by the first press and simultaneously discharging the reinforcing material; and curing the reinforcing material.

The reinforcing material may include naturally curable resin.

Discharging the reinforcing material may be performed for a time period shorter than the second time period.

The first press and the second press of the bonding apparatus may be spaced apart from each other.

The first press and the second press may be movable in a vertical direction.

Embodiments may be realized by providing a display device, including a plurality of pixels in a display area of a first substrate; a second substrate smaller than the first substrate, the second substrate being on the first substrate; a driver integrated circuit (IC) in a non-display area of the first substrate; and a reinforcing material between the second substrate and the driver IC, the reinforcing material having an embossed upper surface.

The reinforcing material may be spaced apart from the driver IC.

The reinforcing material may include one or more of epoxy, acrylate, urethane acrylate, or cyanoacrylate.

The reinforcing material may have viscosity of 1000 cp or higher and 4000 cp or lower.

### BRIEF DESCRIPTION OF THE DRAWINGS

Features will become apparent to those of skill in the art by describing in detail exemplary embodiments with reference to the attached drawings in which:

FIG. 1 illustrates a plane view of a display device according to an embodiment;

FIG. 2 illustrates a cross-sectional view of a display area of FIG. 1;

FIG. 3 illustrates a cross-sectional view of a bonding apparatus for fabricating the display device of FIG. 1;

FIG. 4 illustrates a plane view of a lower surface of a first press unit of the bonding apparatus of FIG. 3;

FIGS. 5 and 6 illustrate cross-sectional views of a method of fabricating the display device of FIG. 1 using the bonding apparatus of FIG. 3;

FIG. 7 illustrates a perspective view of the display device fabricated by the method of FIGS. 5 and 6; and

FIGS. 8 and 9 are a cross-sectional view and a perspective view, respectively, of an alternative form of the reinforcing material of the display device fabricated by the method of FIGS. 5 and 6.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Although the terms “first”, “second”, and so forth are used to describe diverse constituent elements, such constituent elements are not limited by these terms. These terms are used only to discriminate a constituent element from other constituent elements. Accordingly, in the following description, a first constituent element may be a second constituent element. Further, the use of “may” when describing embodiments relates to “one or more embodiments.”

Hereinafter, embodiments will be described with reference to the drawings.

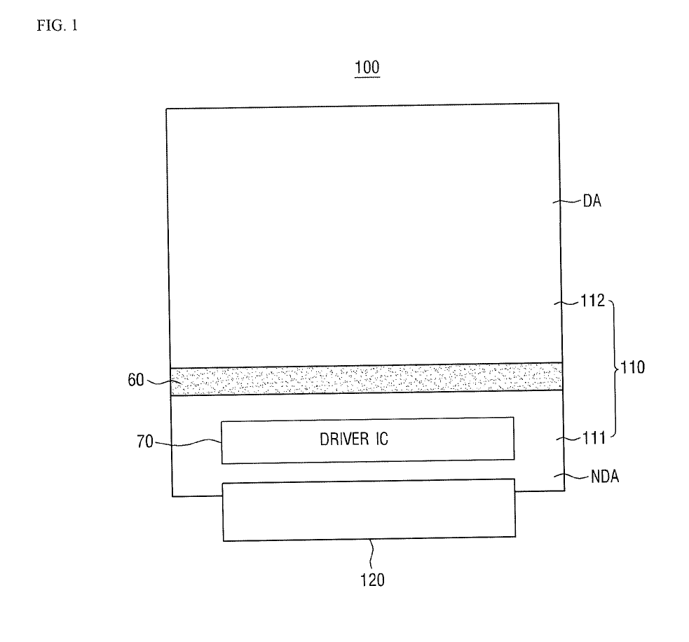

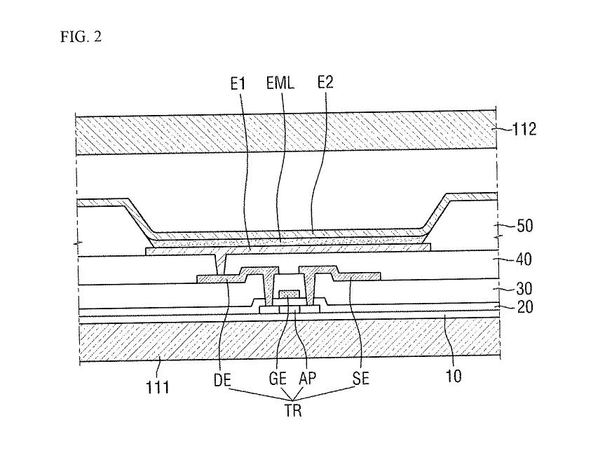

FIG. 1 illustrates a plane view of a display device according to an embodiment, and FIG. 2 illustrates a cross-sectional view of a display area of FIG. 1.

Referring to FIG. 1, a display device 100 according to an embodiment may include a display panel 110 and a flexible printed circuit board 120.

The display panel 110 may include a first substrate 111 and a second substrate 112 facing the first substrate 111. The first substrate 111 and the second substrate 112 may be bonded to each other by a sealant. A plurality of pixels may be arranged on the first substrate 111 to display an image, and the area in which the pixels may be arranged may be a display area DA. The first substrate 111 and the second substrate 112 may have sizes different from each other. For example, as shown in FIG. 1, the first substrate 111 may be larger than the second substrate 112, and the first substrate 111 may further have a non-display area NDA in which a driver integrated circuit (IC) 113 for driving, for example, a plurality of pixels, may be arranged. The display panel 110 may be one of a liquid crystal display, an electrophoretic display, an organic light emitting display, an inorganic electroluminescent display, a field emission display, a surface-conduction electron emitter display, a plasma display, and a cathode ray display. An example of an organic light emitting display will be explained with reference to FIGS. 2 to 9.

A plurality of pixels may be arranged in the display area DA, and each pixel may include a switching element, for example, thin film transistors turned on/off according to a control signal applied from the flexible printed circuit board 120, and a light emitting element which emits light according to a control of the switching element. The display area DA will be discussed in more detail with reference to FIG. 2 on a single pixel basis, in which the display area DA may include the first substrate 111, a buffer layer 10, a semiconductor layer AP, a gate electrode GE, a source electrode SE, a drain electrode DE, a gate insulating layer 20, an interlayer insulating layer 30, a planarization layer 40, a pixel define layer 50, a first electrode E1, an emission layer (EML), a second electrode E2 and the second substrate 112.

The first substrate 111 may be formed of, e.g., include, a transparent insulating material. The transparent insulating material may be, for example, glass, quartz, ceramic, and plastic. The first substrate 111 may have a flat plate shape, and may be formed of, e.g., include, a flexible material that may be easily bent by external force.

The buffer layer 10 may be formed on the first substrate 111. The buffer layer 10 may prevent penetration of impurity elements to flatten an upper surface of the first substrate 111. The buffer layer 10 may be one of a silicon nitride (SiNₓ) layer, a silicon oxide (SiO₂) layer, and a silicon oxynitride (SiOₓN_{y}) layer. The buffer layer 10 may not be an essential component, and may be omitted in other embodiments.

The semiconductor layer AP may be formed on the buffer layer 10. The semiconductor layer AP may be formed of, e.g., include, an amorphous silicon layer or a polycrystalline silicon layer. The semiconductor layer AP may include an impurity-undoped channel region, and a source region and a drain region which are provided at both sides of the channel region and doped with p+ type dopants to contact the source electrode SE and the drain electrode DE, respectively. In an embodiment, the impurities doped to the semiconductor layer AP may be P-type impurities including boron (B). The impurities doped to the semiconductor layer AP may vary depending on embodiments.

The gate insulating layer 20 may be formed on the semiconductor layer AP. The gate insulating layer 20 is provided to achieve insulation between the gate electrode GE and the semiconductor layer AP. The gate insulating layer 20 may be formed of, e.g., include, silicon nitride (SiNₓ) or silicon oxide (SiO₂).

The gate electrode GE may be arranged on the gate insulating layer 20 such that the gate electrode GE may be overlapped with at least a portion of the semiconductor layer AP. Whether to allow the semiconductor layer AP to be conductive or non-conductive may be controlled by the voltage applied from an external source to the gate electrode GE. For example, when a relatively higher voltage is applied to the gate electrode GE, the semiconductor layer AP may become conductive to electrically interconnect the drain electrode DE and the source electrode SE, and when a relatively lower voltage is applied to the gate electrode GE, the semiconductor layer AP may become non-conductive to achieve insulation between the drain electrode DE and the source electrode SE.

The interlayer insulating layer 30 may be formed on the gate electrode GE. The interlayer insulating layer 30 may cover the gate electrode GE to insulate the gate electrode GE from the source electrode SE and the drain electrode DE. The interlayer insulating layer 30 may be formed of, e.g., include, silicon nitride (SiNₓ) or silicon oxide (SiO₂).

The source electrode SE and the drain electrode DE may be provided on the interlayer insulating layer 30. The source electrode SE and the drain electrode DE may be connected to the semiconductor layer AP via a through hole penetrating through the interlayer insulating layer 30 and the gate insulating layer 20. The source electrode SE and the drain electrode DE may constitute a thin film transistor TR together with the gate electrode GE and the semiconductor layer AP, and the thin film transistor TR may determine whether to transmit a signal transmitted to the source electrode SE to the drain electrode DE based on the voltage applied to the gate electrode GE.

The planarizing layer 40 may be formed on the interlayer insulating layer 30, the source electrode SE and the drain electrode DE. The planarizing layer 40 may be formed to cover step differences at upper surfaces of the source electrode SE and the drain electrode DE to help achieve improved luminous efficiency of the emission layer provided on the planarizing layer 40. The planarizing layer 40 may be formed of, e.g., include, one or more of polyacrylate resin, epoxy resin, phenolic resin, polyamide resin, polyimide rein, unsaturated polyester resin, polyphenylene ether resin, poly phenylenesulfide resin, or benzocyclobutene (BCB). The planarizing layer 40 may have a via hole formed therein.

The first electrode E1 may be arranged on the planarizing layer 40 and beneath the emission layer EML. The first electrode E1 may be electrically connected to the drain electrode DE through the via hole formed in the planarizing layer 40 to transmit a signal applied to the drain electrode DE to a lower portion of the emission layer EML. The first electrode E1 may be formed of, e.g., include, a reflective conductive material, a transparent conductive material or a semitransparent conductive material. For example, lithium (Li), calcium (Ca), lithium/calcium fluoride (LiF/Ca), lithium/aluminum fluoride (LiF/Al), aluminum (Al), silver (Ag), magnesium (Mg), or gold (Au) may be used as the reflective conductive material, indium tin oxide (ITO), indium zinc oxide (IZO), zinc oxide (ZnO), or indium oxide (In₂O₃) may be used as the transparent conductive material, and a co-deposited material including either or both magnesium (Mg) and silver (Ag), or one or more of magnesium (Mg), silver (Ag), calcium (Ca), lithium (Li), or aluminum (Al) may be used as the semitransparent conductive material.

The pixel define layer 50 may be formed on the planarizing layer 40. The pixel define layer 50 may divide a plurality of pixels included in the display device 100 into discrete pixels. The pixel define layer 50 may not cover the whole upper surface of the planarizing layer 40, and may have an opening. The first electrode E1 may be exposed from an upper surface of the pixel define layer 50 through the opening. An organic light emitting element including the emission layer EML may be arranged on the first electrode E1 in the opening. The organic light emitting element may include a hole injection layer, a hole transport layer, an electron transport layer and an electron injection layer.

The emission layer EML may be formed on the first electrode E1. The emission layer EML recombines the hole provided from the first electrode E1 and electron provided from the second electrode E2 to emit light. When the hole and electron are provided to the emission layer EML, the hole and the electron may be combined to produce exciton, and the -produced exciton may change from an excited state to a ground state to emit light. The emission layer EML may include a red emission layer for emitting red color, a green emission layer for emitting green color, and a blue emission layer for emitting blue color. Emission of the emission layer EML may be controlled according to the current flowing between the first electrode E1 and the second electrode E2.

The second electrode E2 may be disposed on the emission layer EML. The second electrode E2 may be formed of, e.g., include, for example, a same material as that of the first electrode E1. The second electrode E2 may be a common electrode disposed in the plurality of pixels included in the display device 100. In an embodiment, the second electrode E2 may be formed only on the emission layer EML. In an embodiment, the second electrode E2 may be disposed all over an upper surface of the emission layer EML and an upper surface of the pixel define layer 50.

The second substrate 112 may be formed of, e.g., include, the same material as that of the first substrate 111, and a description on the material may be replaced by the description on the first substrate 111. A polarizing plate may be arranged on the second substrate 112 to prevent reflection of external light.

A reinforcing material 60 and a driver IC 70 may be provided in the non-display area NDA. The non-display area NDA may further accommodate a signal line electrically connected to the plurality of pixels, and a plurality of pads disposed in the area in which the driver IC 70 is packaged and in the area to which the flexible printed circuit board 120 is attached.

The reinforcing material 60 may be provided between the second substrate 112 and the driver IC 70. It may be desirable to form the reinforcing material 60 such that the reinforcing material 60 may not be in contact with the driver IC 70. Resistance components of the driver IC 70 may be affected by the ingredients of the reinforcing material 60 when the reinforcing material 60 contacts the driver IC 70, which may cause faults in the driver IC 70. The reinforcing material 60 may be a liquid, and may be formed of e.g., include, naturally curable, heat curable or ultraviolet curable resin. For example, cyanoacrylate may be used as a naturally curable material, acrylate may be used as a heat curable material, and epoxy, acrylate, and urethane acrylate may be used as an ultraviolet curable material. The reinforcing material 60 may be applied simultaneously when the driver IC 70 is mounted on the first substrate 111 by a bonding apparatus, and the reinforcing material 60 may support the first substrate 111 and the second substrate 112.

The driver IC 70 receives a control signal transmitted through the flexible printed circuit board 120, and generates and outputs a pixel drive control signal for driving the plurality of pixels. The driver IC 70 may be mounted on the first substrate 111 by a bonding apparatus through a chip on glass (hereinafter, referred to as “COG”) process.

The flexible printed circuit board 120 may be electrically connected to an external printed circuit board to transmit data and control signals applied from an external source to the display panel 110. The flexible printed circuit board 120 may be electrically connected to the plurality of pads arranged on the first substrate 111, and mounted on the first substrate 111 by a bonding apparatus.

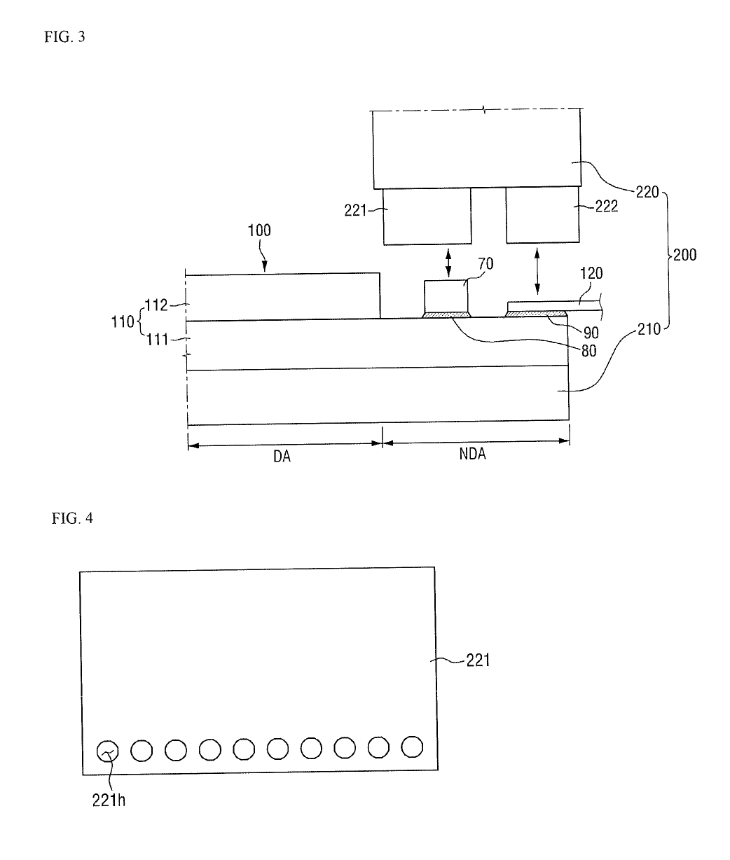

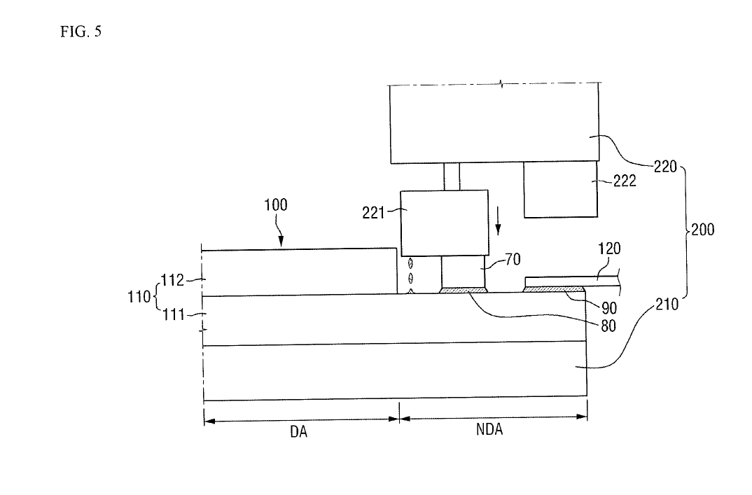

FIG. 3 illustrates a cross-sectional view of a bonding apparatus for fabricating the display device of FIG. 1, and FIG. 4 illustrates a plane view of a lower surface of a first press unit of the bonding apparatus of FIG. 3

Referring to FIG. 3, a bonding apparatus 200 for fabricating the display device 100 according to the embodiment may include a stage 210 and a bonding head 220. The bonding apparatus 200 may mount the driver IC 70 and the flexible printed circuit board 120 onto the first substrate 111 through a thermal compression process.

The stage 210 may support the display panel 110 when a first electrical connection element 80 and a second electrical connection element 90 are thermo-compressed to bond the driver IC 70 and the flexible printed circuit board 120 to the non-display area NDA of the display panel 110.

The bonding head 220 may be arranged above the stage 210 to substantially press the driver IC 70 and the flexible printed circuit board 120 to be thermo-compressed. The bonding head 220 may include a first press unit 221 and a second press unit 222 which are movable in a vertical direction.

The first press unit 221 may be arranged above the driver IC 70 and configured to apply heat and pressure to the driver IC 70. The first press unit 221 may move vertically toward the stage 210 to pre-compress the driver IC 70 under first pre-compression pressure and first pre-compression temperature for a first pre-compression time period, and then perform a main compression on the driver IC 70 under first main compression pressure and first main compression temperature, and the driver IC 70 may be mounted onto the first substrate 111. The driver IC 70 and the plurality of pads on the first substrate 111 may be electrically connected with each other by a first anisotropic conductive film 80 including a conductive ball and adhesive resin.

The first press unit 221 may have an interior filled with the liquid reinforcing material 60. The liquid reinforcing material 60 which fills the first press unit 221 may be discharged through a plurality of discharge ports 221h formed in a lower surface of the first press unit 221, for example, a surface of the first press unit 221 facing the stage 210 during the pre-compression being performed on the driver IC 70, as shown in FIG. 4, and heat-cured during the first main compression being performed on the driver IC 70. The first press unit 221 may be formed larger than a conventional one, and the discharge ports 221h may be formed in the first press unit 221 such that the discharge ports 221h correspond to the area where the reinforcing material 60 is to be provided on the first substrate 111, for example, an area between the second substrate 112 and the driver IC 70. In an embodiment, heat-curable acrylate may be used as the liquid reinforcing material 60. In an embodiment, the reinforcing material 60 may be discharged during the first pre-compression being performed on the driver IC 70 and cured during the first main compression being performed on the driver IC 70. In an embodiment, the reinforcing material 60 may be discharged during the first main compression and naturally cured. The liquid reinforcing material 60 may be hardened into different forms on the first substrate 111 depending on the viscosity of the liquid reinforcing material 60, and this will be discussed in more detail later.

The time period, pressure, and temperature of the first pre-compression in which the first press unit 221 pre-compresses the driver IC 70 may be shorter, smaller and lower than those of the first main compression. However, the process condition of the first press unit may vary depending on the type of the driver IC 70 and the first anisotropic conductive film 80.

The second press unit 222 may be arranged above the flexible printed circuit board 120 and configured to apply heat and pressure to the flexible printed circuit board 120. The second press unit 222 may move vertically toward the stage 210 to pre-compress the flexible printed circuit board 120 under second pre-compression pressure and second pre-compression temperature for a second pre-compression time period, and then perform a main compression on the flexible printed circuit board 120 under second main compression pressure and second main compression temperature, and the flexible printed circuit board 120 may be mounted onto the first substrate 111. The flexible printed circuit board 120 and the plurality of pads on the first substrate 111 may be electrically connected with each other by a second anisotropic conductive film 90 including a conductive ball and adhesive resin. The time period, pressure, and temperature of the second pre-compression in which the second press unit 222 pre-compresses the flexible printed circuit board 120 may be shorter, smaller and lower than those of the second main compression. However, the process condition of the second press unit 222 may vary depending on the type of the flexible printed circuit board 120 and the second anisotropic conductive film 90. The second pre-compression operation and second main compression operation of the second press unit 222 may be performed independently of or in connection with the first pre-compression operation and second pre-compression operation of the first press unit 221. However, the time period, temperature and pressure of the second pre-compression performed on the flexible printed circuit board 120 may differ from the time period, temperature and pressure of the first pre-compression performed on the driver IC 70, and the time period, temperature and pressure of the second main compression performed on the flexible printed circuit board 120 may differ from the time period, temperature and pressure of the first main compression performed on the driver IC 70.

FIG. 3 depicts that a single bonding apparatus may include both the first press unit 221, which compresses the driver IC 70, and the second press unit 222, which compresses the flexible printed circuit board 120. In an embodiment, an apparatus for compressing or bonding the driver IC 70 and an apparatus for compressing or bonding the flexible printed circuit board 120 may be separated from each other.

As described above, the bonding apparatus 200 for fabricating the display device 100 according to the embodiment may be configured such that the liquid reinforcing material 60 provided in the first press unit 221 may be discharged and formed on the first substrate 111 when mounting the driver IC 70 onto the first substrate 111, and process time may be shortened and faults in the driver IC 70 may be reduced.

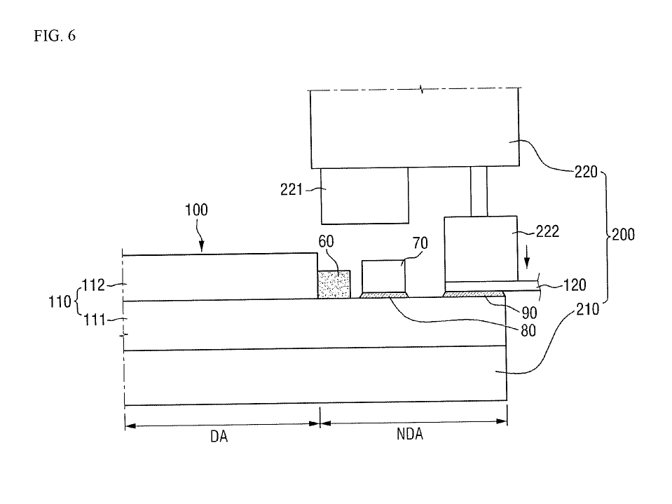

FIGS. 5 and 6 illustrate cross-sectional views of a method of fabricating the display device of FIG. 1 using the bonding apparatus of FIG. 3.

Referring to FIG. 5, the first anisotropic conductive film 80 is disposed on the pads in the non-display area NDA of the first substrate 111 of the display panel 110 provided on the stage 210, and then the driver IC 70 is aligned on the first anisotropic conductive film 80.

Subsequently, the first press unit 221 of the bonding head 220 moves in a vertical direction toward the stage 210 to pre-compress the driver IC 70 under first pre-compression pressure and temperature for the first pre-compression time period. At this moment, the first pre-compression pressure and the first pre-compression temperature of the first press unit 221 are transmitted to the first anisotropic conductive film 80 through the driver IC 70. The plurality of discharge ports 221h of the first press unit 221 open in accordance with the control of a control unit of the bonding apparatus during the first pre-compression time period for pre-compressing the driver IC 70 by the first press unit 221, and the liquid reinforcing material 60 provided in the first press unit 221 is discharged through the plurality of open discharge ports 221h. In an embodiment, the reinforcing material 60 may fill the interior of the first press unit 221.

The first pre-compression may be performed on the driver IC 70, for example, under the pressure of approximately 1 MPa and temperature of approximately 80° C. for approximately 1 second. The reinforcing material 60 may also be discharged for 1 second for example. Upon completion of the first pre-compression on the driver IC 70 and discharge of the reinforcing material 60, the first press unit 221 may move in a vertical direction to be spaced apart from the driver IC 70 and the reinforcing material 60. The vertical movement of the first press unit 221 may be carried out by a movement driving apparatus connected to the first press unit 221, the first pre-compression pressure of the first press unit 221 may be controlled by a compression apparatus connected to the first press unit 221, and the first pre-compression temperature of the first press unit 221 may be controlled by a heater connected to the first press unit 221.

Subsequently, the first press unit 221 of the bonding head 220 moves again in a vertical direction toward the stage 210 to be placed on the driver IC 70. The plurality of discharge ports 221h formed in the lower surface of the first press unit 221 may be controlled to be closed. The moved first press unit 221 may perform a main-compression on the driver IC 70 under the first main compression pressure and first main compression temperature for the first main compression time period. At this moment, the first main compression pressure and the first main compression temperature of the first press unit 221 may be transmitted to the first anisotropic conductive film 80 and the reinforcing member 60 through the driver IC 70. An insulator of the conductive ball of the first anisotropic conductive film 80 is broken and the driver IC 70 is electrically connected to the plurality of pads on the first substrate 111 through the conductive ball, and the driver IC 70 is fixed on the first substrate 111 through the adhesive resin. The first main compression temperature of the first press unit 221 may be transmitted to the reinforcing material 60 discharged near the driver IC 70, and the reinforcing material 60 may be heat-cured by the first main compression temperature. The first main compression pressure and the first main compression temperature of the first press unit 221 are higher than the aforementioned first pre-compression pressure and first pre-compression temperature. For example, the first main compression may be performed by the first press unit 221 under the pressure of approximately 130 mpa and the temperature of approximately 220° C. for 5 seconds.

Referring now to FIG. 6, the second anisotropic conductive film 90 is disposed on the plurality of pads arranged on an end area of the first substrate 111, the flexible printed circuit board 120 is aligned on the second anisotropic conductive film 90, and the second press unit 222 of the bonding head 210 moves in a vertical direction toward the stage 210 to pre-compress the flexible printed circuit board 120 under the second pre-compression pressure and second pre-compression temperature for the second pre-compression time period. The second pre-compression time period, the second pre-compression pressure and second pre-compression temperature of the second press unit 222 may be identical to the first pre-compression time period, the first pre-compression pressure and first pre-compression temperature of the first press unit 221.

After pre-compressing the flexible printed circuit board 120 onto the first substrate 111, the second press unit 222 may move in a vertical direction to be spaced apart from the flexible printed circuit board 120. The vertical movement of the second press unit 222 may be carried out by a movement driving apparatus connected to the second press unit 222, the pre-compression pressure of the second press unit 222 may be controlled by a compression apparatus connected to the second press unit 222, and the pre-compression temperature of the second press unit 222 may be controlled by a heater connected to the second press unit 222.

Subsequently, the second press unit 222 of the bonding head 210 moves again in a vertical direction toward the stage 210 to be placed on the flexible printed circuit board 120. Then, the second press unit 222 may perform a main-compression on the flexible printed circuit board 120 under the second main compression pressure and second main compression temperature for the second main compression time period. At this moment, the second main compression pressure and the second main compression temperature of the second press unit 222 may be transmitted to the second anisotropic conductive film 90 through the flexible printed circuit board 120. An insulator of the conductive ball of the second anisotropic conductive film 90 is broken and the flexible printed circuit board 120 is electrically connected to the plurality of pads on the first substrate 111 through the conductive ball, and the flexible printed circuit board 120 is fixed on the first substrate 111 through the adhesive resin. The second main compression pressure and the second main compression temperature of the second press unit 222 may be higher than the aforementioned second pre-compression pressure and second pre-compression temperature, and equal to or lower than the first main compression pressure and the first main compression temperature of the first press unit 221.

In an embodiment, the reinforcing material 60 may be discharged during the pre-compression being performed on the driver IC 70 and cured during the main compression being performed on the driver IC 70. In an embodiment, the reinforcing material 60 may be discharged during the main compression being performed on the driver IC 70 and naturally cured. The discharging timing may vary depending on the composition of the reinforcing material 60.

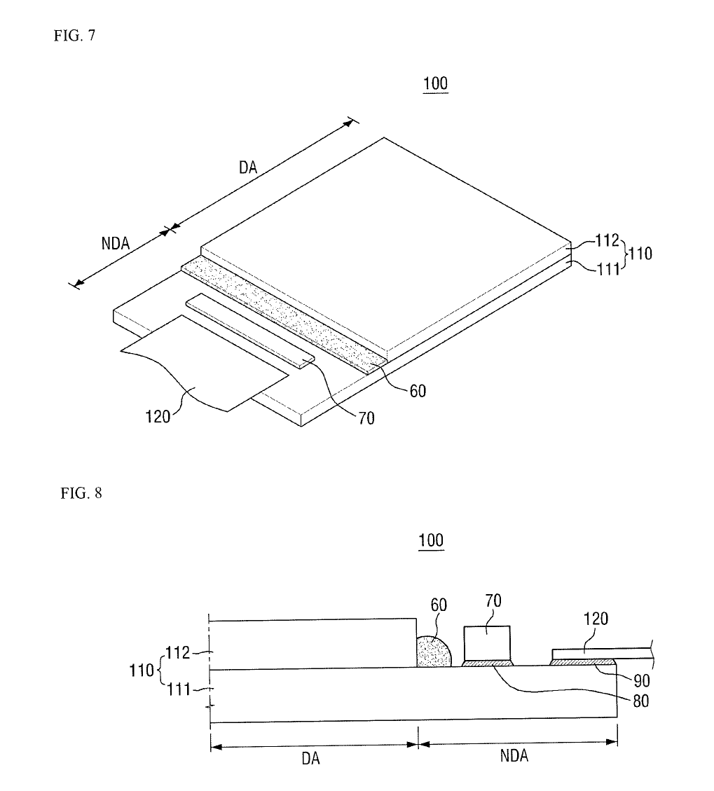

FIG. 7 is a perspective view of the display device fabricated by the method of FIGS. 5 and 6.

Referring to FIG. 7, the reinforcing material 60 provided in the non-display area NDA may be formed on the first substrate 111 between the second substrate 112 and the driver IC 70. As shown in FIG. 7, the reinforcing material 60 may have an upper surface which is roughly flat since the reinforcing material 60 has low viscosity. The viscosity of the reinforcing material 60 may vary depending on the composition of the reinforcing material 60, and may be, for example, 100 cp or higher and lower than 1000 cp.

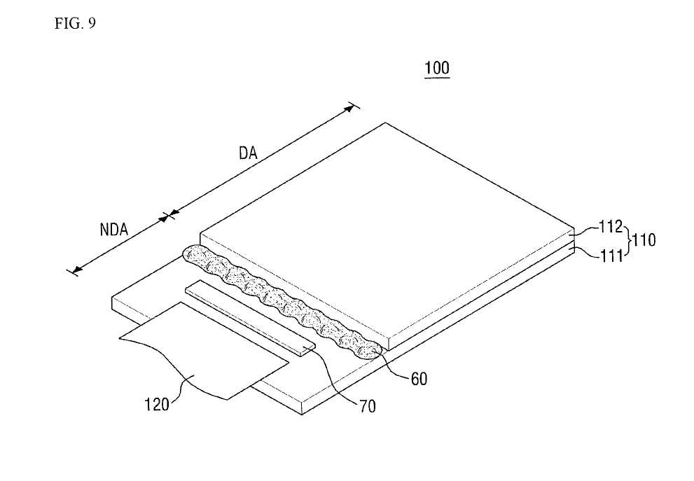

FIGS. 8 and 9 illustrate a cross-sectional view and a perspective view, respectively, of an alternative form of the reinforcing material of the display device fabricated by the method of FIGS. 5 and 6.

Referring to FIGS. 8 and 9, the reinforcing material 60 formed in the non-display area NDA may be arranged on the first substrate 111 between the second substrate 112 and the driver IC 70. The reinforcing material 60 may have high viscosity, and the upper surface of the reinforcing member 60 may be embossed. The viscosity of the reinforcing material 60 may vary depending on the composition of the reinforcing material 60, and may be, for example, 1000 cp or higher and 4000 cp or lower.

In one embodiment, the bonding apparatus 200 employed in fabricating the display device 100 may have reinforcing material discharge ports 221h to discharge the reinforcing material 60 simultaneously when the driver IC 70 provided in the non-display area NDA of the display panel 110 is packaged on the first substrate 111, the number of processes and unit price of products may be reduced, the necessity of significantly increasing the space between the driver IC 70 and the second substrate 112 may be eliminated, and a bezel area may be reduced.

By way of summation and review, a flat panel display device may include a display panel in which a plurality of pixels is arranged, and a printed circuit board electrically connected to the display panel via a flexible circuit board. The display panel may include an upper substrate and a lower substrate, and the upper substrate and the lower substrate may be bonded to each other by a sealant layer, and a reinforcing material may be formed between a driver IC arranged on the lower substrate and the upper substrate to prevent delamination. The reinforcing material may be formed after placing the driver IC on the lower substrate.

The aforementioned reinforcing material may be applied on the lower substrate while a reinforcing material applicator needle for discharging a reinforcing material passes over an upper surface of the lower substrate on which the driver IC is arranged.

When the reinforcing material is applied on the lower substrate as described above, the reinforcing material applicator needle may hit the driver IC. If the reinforcing material applicator needle hits the driver IC, defects in the flat panel display device may occur.

If spacing between the upper substrate and the driver IC is increased to prevent the reinforcing material applicator needle from hitting the driver IC, a bezel area may increase.

Provided is a method of fabricating a display device in which a reinforcing material application method may be improved, and defects in a flat panel display device and a bezel area may be reduced. Also provided is a display device in which a reinforcing material application method may be improved, and defects in a flat panel display device and a bezel area may be reduced.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of fabricating a display device using a bonding apparatus, the method comprising:
arranging a second substrate on a first substrate in which a plurality of pixels is formed, and bonding the first substrate and the second substrate to each other;
providing the first substrate and the second substrate on a stage, and
compressing a driver integrated circuit (IC) on the first substrate and simultaneously forming a reinforcing material on the first substrate; and
compressing a flexible printed circuit board on the first substrate.

2. The method as claimed in claim 1, wherein:
the bonding apparatus includes a first press and a second press,
the driver IC is compressed on the first substrate using the first press, and
the flexible printed circuit board is compressed on the first substrate using the second press.

3. The method as claimed in claim 2, wherein compressing the driver IC and simultaneously forming the reinforcing material further includes:
aligning the driver IC on the first substrate, and pre-compressing the driver IC under a first temperature and a first pressure for a first time period by the first press and simultaneously discharging the reinforcing material through the first press; and
performing a main compression on the driver IC under a second temperature and a second pressure for a second time period by the first press and simultaneously curing the reinforcing material.

4. The method as claimed in claim 2, wherein the first press has a plurality of discharge ports formed in a surface of the first press facing the stage to discharge the reinforcing material.

5. The method as claimed in claim 4, wherein the reinforcing material is formed on the first substrate between the second substrate and the driver IC.

6. The method as claimed in claim 4, wherein the reinforcing material is in liquid form embedded in the first press.

7. The method as claimed in claim 4, wherein the reinforcing material is formed of heat-curable resin.

8. The method as claimed in claim 7, wherein the reinforcing material has viscosity of 100 cp or higher and 4000 cp or lower.

9. The method as claimed in claim 3, wherein the first time period is shorter than the second time period, and the first temperature and the first pressure are lower than the second temperature and the second pressure.

10. The method as claimed in claim 2, wherein compressing the driver IC and simultaneously forming the reinforcing material further includes:
aligning the driver IC on the first substrate, and pre-compressing the driver IC under a first temperature and a first pressure for a first time period by the first press;
performing a main compression on the driver IC under a second temperature and a second pressure for a second time period by the first press and simultaneously discharging the reinforcing material; and
curing the reinforcing material.

11. The method as claimed in claim 10, wherein the reinforcing material includes naturally curable resin.

12. The method as claimed in claim 10, wherein discharging the reinforcing material is performed for a time period shorter than the second time period.

13. The method as claimed in claim 3, wherein the first press and the second press of the bonding apparatus are spaced apart from each other.

14. The method as claimed in claim 13, wherein the first press and the second press are movable in a vertical direction.

15. A display device, comprising:
a plurality of pixels in a display area of a first substrate;
a second substrate smaller than the first substrate, the second substrate being on the first substrate;
a driver integrated circuit (IC) in a non-display area of the first substrate; and
a reinforcing material between the second substrate and the driver IC, the reinforcing material having an embossed upper surface.

16. The display device as claimed in claim 15, wherein the reinforcing material is spaced apart from the driver IC.

17. The display device as claimed in claim 16, wherein the reinforcing material includes one or more of epoxy, acrylate, urethane acrylate, or cyanoacrylate.

18. The display device as claimed in claim 17, wherein the reinforcing material has viscosity of 1000 cp or higher and 4000 cp or lower.
